(19) United States
(12) Patent Application Publication
(10) Pub. No.: US 2005/0069788 A1
(43) Pub. Date: Mar. 31, 2005

(54) Photomask, photomask manufacturing method and semiconductor device manufacturing method using photomask

(75) Inventors: Toshihiko Tanaka, Hyogo (JP); Shuji Nakao, Hyogo (JP)

Correspondence Address: McDermott, Will & Emery LLP, 600 13th Street, N.W., Washington, DC, 20005-3096, US

(73) Assignee: RENESAS TECHNOLOGY CORP.

(21) Appl. No.: 10/952,783

(22) Filed: Sep. 30, 2004

(30) Foreign Application Priority Data
Sep. 30, 2003 (JP) 2003-341023(P)

(51) Int. Cl. G03F 9/00; G03C 5/00

(52) U.S. Cl. 430/5; 430/311; 430/312; 430/313; 430/322; 430/323

(57) ABSTRACT

The present invention provides a photomask including a field which attenuates exposure light and causes the exposure light passed therethrough to have the same phase as that of exposure light passed through a main pattern for transfer, and a rim pattern which causes exposure light to be transmitted through the rim region of the main pattern and causes the exposure light passed therethrough to have an opposite phase to that of the transmitted light from the main pattern. Use of this photomask makes it possible to provide a photomask and a semiconductor device manufacturing method which have a practical resolution applicable to 65-nm nodes, have no defect, and can be subjected to defect inspections.

### BACKGROUND OF THE INVENTION

1. Field of the Invention

The present invention relates to manufacturing methods of semiconductor devices, electronic devices and the like, and more particularly to manufacturing methods of semiconductor devices suitable for manufacturing semiconductor devices including micro-hole patterns, photomasks for use therein, and manufacturing methods of such photomasks.

2. Description of the Background Art

In manufacturing a semiconductor integrated circuit device, a lithography technique is utilized as a method for transferring a micro-pattern to a semiconductor wafer. In a lithography technique, a projection exposure device is mainly employed, and the pattern of a photomask mounted on the projection exposure device is transferred onto a semiconductor wafer to form a device pattern.

In recent years, for coping with increasing device densities and requirements for improvement of device operating speeds, there have been advances in miniaturization of patterns to be formed. Under this background, a light exposure method referred to as a half tone phase shift method has been utilized. A half-tone-phase-shift type photomask (hereinafter, referred to as half tone phase shift mask) is a mask including a film (hereinafter, referred to as a half tone film) semi-transparent to exposure light, which has been formed on a transparent substrate (blank). The transmittance of the film with respect to exposure light is generally adjusted to 1% to 25%. Further, the film is adjusted such that there will be a phase difference between exposure light passed through the film and exposure light which did not pass the film. The phase difference which offers the highest resolution performance is 180° and an odd multiple of 180°. However, a phase difference within the range of 180±90° is effective in improving the resolution. It is known that use of half tone phase shift mask generally improves the resolution by 5 to 20%. As the half tone film, an inorganic film formed by MoSi, ZrSixOy, CrFxOy, SiNx, SiON or the like is employed, wherein x and y are suffixes each designating a constituent ratio.

In the case where a hole pattern is formed by the half tone phase shift method, a half tone phase shift mask is employed in which a half tone film 22 is formed on the field region and an opening 23 is formed at the area of the half tone film for forming the hole, as illustrated in FIG. 2. Further, as the transparent substrate 21 in FIGS. 2A and 2B, a silica glass is generally employed. FIG. 2A is a plan view of the mask and FIG. 2B is a cross sectional view illustrating the cross section taken along the line IIA-IIA of FIG. 2A. The half tone phase shift is described in Japanese Patent Laying-Open No. 05-181257, for example.

Also, as a method for improving the resolution and the light exposure margin for hole patterns, a photomask called as an OL-PSM (Outline-Phase Shifting Mask) has been suggested. A general outline of this mask will be described using FIG. 3A which is a plan view of the mask and FIG. 3B which is a cross sectional view illustrating a cross section taken along the line IIIA-IIIA of FIG. 3A. In the figures, there are shown a glass substrate 31, a half tone film 32, a main pattern 33, and secondary pattern 34. Half tone film 32 is a film for inverting the phase of exposure light passing therethrough and for attenuating the exposure light to a desired value. The half tone film in the aforementioned half tone phase shift mask is often employed.

In the main pattern region 33, glass substrate 31 is trenched such that exposure light passed through the main pattern region and exposure light passed through half tone film 32 will be in phase. Around and near the main pattern, a secondary pattern 34 is placed. Secondary pattern 34 has a dimension which is not transferred itself and is generally 1/10 to ⅓ of that of the main pattern 32. Although secondary pattern 34 is placed adjacent to the main pattern, it is spaced from the main pattern and does not abut it. Therefore, as illustrated in FIG. 3B, there is a micro half tone film pattern formed between the secondary pattern and the main pattern. The exposure light passed through the secondary pattern has a phase opposite to that of the exposure light passed through the main pattern and the half tone film.

The use of this photomask increases the depth of focus and improves the optical image contrast, which offers a light exposure margin and also reduces MEF, which will be described later, to near 1. Thus, the margin of mask dimension variation is also increased. The OL-PSM is described in “Improved outline phase shifting mask (OL-PSM) for reduction of the mask error enhancement factor”, (Optical Microlithography XVI, Anthony Yen, Editor, Proceedings of SPIE Vol. 5040 (2003), pp1220-1230).

MEF (Mask Error enhance Factor) is an index indicating how much the dimension difference ΔLm in the transferred pattern has been amplified from the dimension difference ΔLw on the mask and is expressed as the following Equation (1), wherein M is ¼ in the case of using a 4× lens, for example.
MEF=ΔLm/(M·ΔLw) Equation (1)

In the case of a micro pattern such as that requiring the use of the half tone phase shift mask, the MEF is generally 2 to 3, or namely dimension variations in the mask is transferred with an amplification degree of 2M to 3M. For example, when using a scanner with a reduction ratio of 4, the ratio of variations in the transferred dimension to variations in the mask dimension should be ¼. However, in the case of M=4, this ratio becomes 1, namely dimension variations on a wafer becomes equal to dimension variations on the mask.

The aforementioned conventional method has problems as follows.

Half tone phase shift masks improve resolutions as compared with conventional Cr masks. However, the effect of the resolution improvement remains at 5 to 20%. For 65-nm-node SoC (System on Silicon), which has been currently developed, there is a need to form holes having a diameter of 90 or 80 nm with a 200 nm pitch pattern to isolated pattern, using ArF lithography with a wavelength of 193 nm.

Improvements of resolutions have been attained by increasing the NAs of lenses. However, this decreases the depths of focus because of the tread off therebetween, and thus the substantial resolutions have plateaued, in consideration of the depths of focus. The depth of focus for 90-nm holes is about 150 nm and the MEF is about 5. In consideration with the wafer flatness, lens distortions, the focus detection accuracy, and the focus control accuracy, the depth of focus required for 65-nm-node is 250 nm and there is a shortage of the depth of focus. This means that resolution defects frequently occur. Furthermore, the MEF is large, making it difficult to manufacture a mask. The required accuracy of resist hole diameter is about 11 nm, and in order to achieve this, the mask must be formed with an dimension accuracy of about 8.8 nm assuming that the accuracy of resist hole diameter depends on only mask factors. Since the dimension accuracy on the wafer does not depend only on mask factors, it is extremely difficult to form hole patterns for 65-nm-nodes using a half tone phase shift mask.

With OL-PSM masks, the depth of focus for 90-nm holes is about 250 nm and the MEF is about 1, which enables wafer resolution. However, a secondary pattern 36 illustrated in FIG. 3B is required to have a line width of about 200 nm on the mask, and accordingly a half tone partition wall pattern 37 formed between the secondary pattern and the main pattern will be required to have a width of 80 nm on the mask. There is a small contact area between the partition wall pattern and the glass substrate and therefore abrasions of the second pattern will occur during mask cleaning which is necessary for eliminating mask defects. Furthermore, the main pattern and the secondary pattern are formed in different drawing processes, and misalignments generated during the drawing processes further narrows the width of one of the partition wall patterns, which facilitates abrasions. Even though the mask has a configuration susceptible to frequent abrasions, mask defect inspections are extremely difficult.

Light-detection type mask defect inspection devices are utilized because of requirements for throughputs. However, even when an ArF excimer laser with a short wavelength is utilized as the detection light for such micro-patterns, such a laser has a wavelength of 193 nm and this is substantially the same dimension as the secondary pattern. Furthermore, for partition wall patterns 37, the dimension of a partition wall pattern 37 is half of the wavelength. Furthermore, these micro-patterns are placed closely to one another, which prevents performing inspections. Detection of detects in the secondary patterns can not be carried out and also even defect inspections for the main pattern can not be carried out since error detection of quasi-defects frequency occur.

As described above, the half tone phase shift light exposure method can not provide practical resolutions applicable to 65-nm nodes. With the OL-PSM, manufacture of a defect-free mask is extremely difficult and mask defect inspections can not be carried out.

### SUMMARY OF THE INVENTION

It is an object of the present invention to provide manufacturing methods of photomasks and semiconductor devices which overcome the problems involved in the aforementioned conventional methods, offer a practical resolution applicable to 65-nm nodes, have no defect, and can be subjected to defect inspections.

The present invention is characterized in that, in order to overcome the aforementioned problems, it provides a photomask in which the field region is capable of attenuating exposure light, the exposure light passed through the field region and the exposure light passed through the main pattern region have substantially the same phase (0°), the exposure light passes through the rim region of the main pattern, and the exposure light passed through the rim region has an opposite phase (180°) to the phase of the exposure light passed through the main pattern. Further, the present invention is characterized in that a semiconductor device is manufactured using this photomask.

According to the present invention, practical resolutions applicable to 65-nm nodes may be ensured. Further, the photomasks provided according to the present invention are defect-free photomasks and can be subjected to defect inspections. This increases the yield of manufactured semiconductor devices.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional structural drawing of main parts of a photomask according to an embodiment of the present invention;

FIG. 2A and FIG. 2B are structural drawings illustrating the structure of a conventional photomask, wherein FIG. 2A is a plan view, and FIG. 2B is a main parts cross sectional structural drawing;

FIG. 3A and FIG. 3B are structural drawings illustrating the structure of a second conventional photomask, wherein FIG. 3A is a plan view, and FIG. 3B is a main parts cross sectional structural drawing;

FIG. 4A and FIG. 4B are structural drawings illustrating the structure of a photomask according to an embodiment of the present invention, wherein FIG. 4A is a plan view, and FIG. 4B is a main part cross sectional structural drawing;

FIG. 5A to 5D are photomask manufacture process diagrams illustrating, in a main part structural diagram, the photomask manufacture processes according to the first embodiment of the present invention;

FIG. 6A to 6D are photomask manufacture process diagrams illustrating, in a main part structural diagram, the photomask manufacture processes according to the first embodiment of the present invention, subsequently to FIGS. 5A to 5D;

FIG. 7A to 7E are photomask manufacture process diagrams illustrating, in a main part structural diagram, the photomask manufacture processes according to another embodiment of the present invention;

FIG. 8A to 8E are semiconductor device manufacturing process diagrams illustrating, in a main part structural diagram, semiconductor device manufacture processes;

FIG. 9 is a first pattern layout diagram of a semiconductor device according to an embodiment of the present invention;

FIG. 10 is a second pattern layout diagram of a semiconductor device according to an embodiment of the present invention; and

FIG. 11 is a third pattern layout diagram of a semiconductor device according to an embodiment of the present invention.

### DESCRIPTION OF THE PREFERRED EMBODIMENTS

### First Embodiment

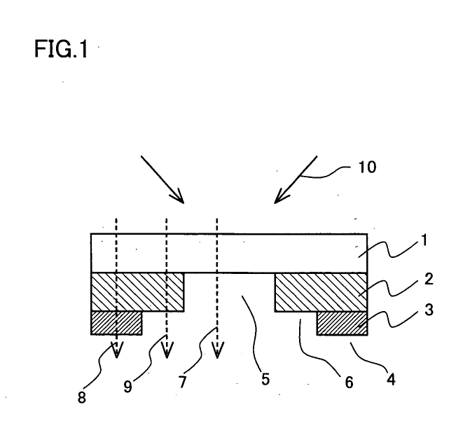

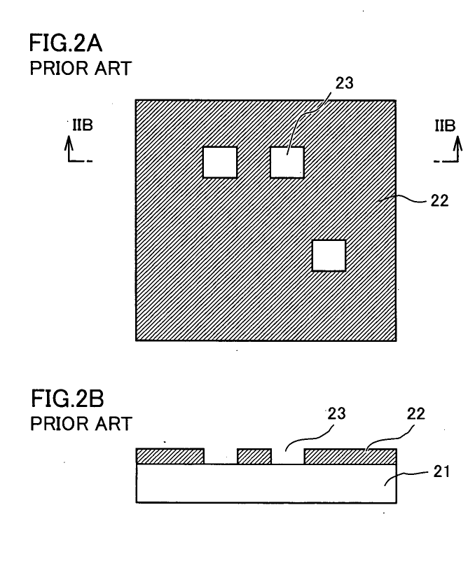

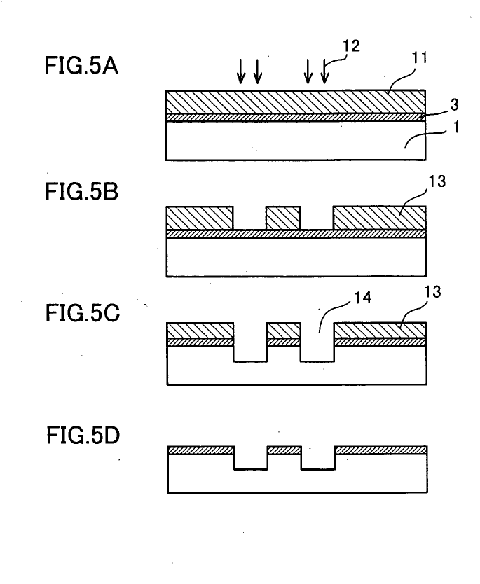

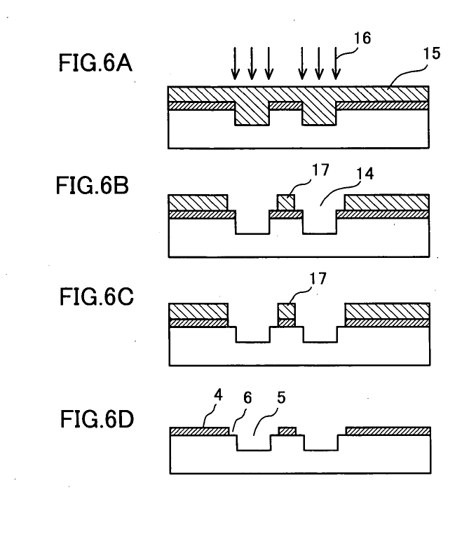

Here, a general outline of the invention will be described using FIG. 1 illustrating the photomask configuration according to an embodiment of the present invention. Subsequently, a first manufacturing method of the photomask will be described using FIGS. 5A to 5D and FIGS. 6A to 6D illustrating the mask manufacturing processes by following the cross sectional configuration of mask main parts.

The photomask is comprised of a glass substrate 1 such as silica glass, a phase shifter material 2 transparent to exposure light, and a half tone material 3 which attenuates the exposure light. Here, “transparent” means a condition which transmits 70% or more of the exposure light, and generally 90% or more of the exposure light. Also, here, “attenuation of light” means that the light transmittance is equal to or less than 25%. However, light transmittance within the range of from 4% to 9% provides a required resolution and is also desirable in preventing so-called sub peak transfer. Sub peak transfer is a phenomenon that light enters a field region to which pattern transfer should not occur from surrounding patterns and interference of light occurs to cause light spots resulting in the formation of abnormal patterns. The area at which half torn material 3 has been formed forms a field 4. A main pattern is formed by an opening 5. A rim region 6 is formed outside of and formed to come in contact with the opening of main pattern 5. This rim region 6 is formed from the glass substrate and the transparent phase shifter material.

Therefore, exposure light 8, which passes thorough the field region, passes thorough the glass substrate, the transparent shifter material and the half tone material. Exposure light 9, which passes thorough the rim region, passes thorough the glass substrate and the transparent shifter material. Exposure light 7, which passes through opening 5 or the main pattern, passes through only the glass substrate. Here, transparent shifter material 2 may be a transparent film, for example, SOG (Spin On Glass) or SiO₂ film formed by CVD (Chemical Vapor Deposition), which has been laminated on the glass substrate and also may be the glass substrate itself Namely, the glass substrate may be partially trenched and the resultant film thickness difference may be utilized to provide such a function. In the case of forming a film, there may be provided an advantage that an etching selection ratio of the film to the glass substrate may be obtained and the film thickness controllability may be improved, thereby improving the phase controllability.

On the other hand, in the case of trenching the glass substrate, there is provided an advantages that blank material cost is low and the problem of the resistance to exposure light irradiation is not induced. The film thickness of transparent phase shifter material 2 is adjusted such that exposure light 7 passing through the main pattern region and exposure light 9 passing through the rim region will have opposite phases, namely there will be a phase difference of 180° or an odd multiple of 1800 therebetween. The phase difference is set to 180±5° and, in the case there is a need for excellent dimension controllability, to within 180±2°. The film thickness that inverts the phase is λ/(2n₁−1), wherein the refractive index of the transparent phase shifter material with respect to exposure light is n1 and the-wavelength of the exposure light is λ. Also, the film thickness of half tone material 3 and the refractive index n₂ of the film of half tone material 3 with respect to exposure light are adjusted such that exposure light 8 passing through the field region and the exposure light passing through the rim region have opposite phases, similarly. The phase difference is set to 180±5° and, in the case there is a need for excellent dimension controllability, to within 180±2°. A 180° phase inversion occurs in the case where the film thickness of half tone material is λ/(2n₂−1). In this case, there is no phase difference between the exposure light passing through the field region and the exposure light passing through the main opening pattern region, and therefore these lights are in phase (0°). The width of the rim region is set to from ⅙ to ⅓ of the width of the main pattern. In the case where the width of the rim region is greater or smaller than this range, the contrast is decreased when forming a micro-pattern with a dimension of approximately one half the exposure light wavelength.

This mask is irradiated with oblique-incident exposure light 10. The oblique-incident illumination of exposure light may be realized by annular illumination, quadrupole illumination, double-pole illumination or the like. The exposure light passed through the field region and the exposure light passed through the main pattern region interfere with each other to generate an optical image which does not have a sufficient contrast but has a low defocus dependency. The exposure light from the rim region having an inversed phase interferes with the light passed through the main pattern region and a slight amount of light leaked from the field region to increase the contrast of the optical image. As a result, light exposure may be carried out with a high resolution and a light exposure margin. Further, in this mask configuration, since the half tone region and the transparent phase shifter region are formed in order to constitute gradual steps, the walls of the respective steps are relatively short, which reduces degradations of optical images due to side wall reflection. Thus, transfer with a high contrast and high resolution may be carried out.

Next, the method for manufacturing this mask will be described using FIGS. 5A to 5D and FIGS. 6A to 6D. First, as illustrated in FIG. 5A, half tone film 3 is formed on glass substrate 1. Here, half tone film 3 is formed such that the aforementioned transmittance and phase difference are provided. A resist 11 is formed thereon and then a desired pattern is drawn by an electron beam 12 or light. Then, as illustrated in FIG. 5B, development is performed to form a resist pattern 13. Then, as illustrated in FIG. 5C, the half tone film and the glass substrate are partially etched using resist pattern 13 as the mask to form openings 14 in the halftone film and the glass substrate. Then, as illustrated in FIG. 5D, resist 13 is removed.

Subsequently, as illustrated in FIG. 6A, a resist 15 is applied. Then, a larger region including the main pattern is drawn by an electron beam 16 or light. Then, development is performed to form a resist pattern 17 having an opening area larger than main pattern 14 so that the rim region outside of the main pattern is exposed, as illustrated in FIG. 6B. Then, as illustrated in FIG. 6C, the half tone film is etched using resist pattern 17 as the mask. Finally, as illustrated in FIG. 6D, resist pattern 17 is removed and cleaned. As described above, the mask consisting of field region 4, rim region 6 and main pattern region 5 was manufactured.

The mask included no micro-partition-wall pattern having a width smaller than 100 nm on the mask. The formed pattern had at minimum a line width of 120 nm on the mask and there was caused no problem of pattern abrasions. Further, the mask included no micro-opening pattern having a line width of 200 nm or the like, which enabled visual defect inspection. Further, any quasi-defect was not observed.

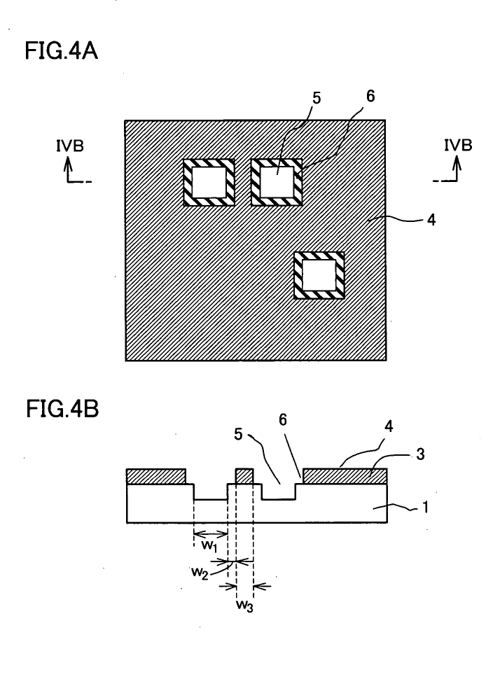

Exposure and transfer evaluations were performed for this mask using an ArF scanner with an NA of 0.78. For hole patterns with a diameter of 90 nm, the depth of focus was 250 nm or more for 190 nm pitch to complete isolation. Further, there was no resolution defect caused by the shortage of the depth of focus. Further, the MEF was appropriately 1 and there was no problem of mask accuracy. The width of the rim region was set to 25 nm. However, the aforementioned depth of focus was ensured for the rim region width range of from 20 nm to 35 nm. The rim region width had a small influence on the transferred dimension and thus the mask had excellent controllability. Further, the formed hole patterns had a dimension of 90 nm, but the opening width (w1 in FIG. 4B) of the main opening portion was 440 nm on the scale on the mask (110 nm on the scale on the wafer).

### Second Embodiment

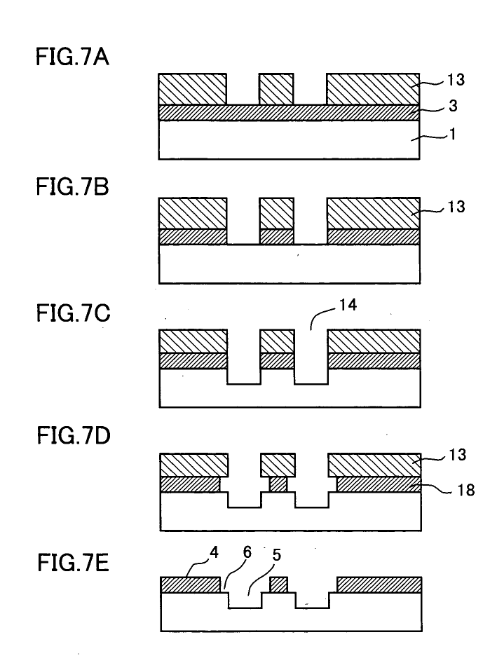

A second embodiment will be described using FIGS. 7A to 7E. According to the present embodiment, there is provided a simplified mask manufacture method. First, as illustrated in FIG. 7A, half tone film 3 and a resist pattern 13 are formed on glass substrate 1. Here, similarly to the first embodiment, half tone film 3 is formed such that the aforementioned transmittance and phase difference are provided. Then, as illustrated in FIG. 7B, the half tone film is etched using resist pattern 13 as the mask, and subsequently, as illustrated in FIG. 7C, the glass substrate is etched to form opening portions 14 with a desired main pattern. The etching depth of the glass substrate is selected to satisfy the aforementioned condition which inverts the phase of exposure light relative to that at the glass substrate surface. Then, as illustrated in FIG. 7D, a selective isotopic etching is applied to the half tone film to form a half tone pattern 18 recessed by the amount of desired rim width. Then, resist pattern 13 is removed and cleaned. As described above, there was manufactured a mask consisting of field region 4, rim region 6 and main pattern region 5 as illustrated in FIG. 7E in which field portion 4 and main pattern portion 5a are in phase and the rim portion is in an opposite phase.

This manufacturing method includes a single drawing process, and a mask having a reduced misalignment between the main pattern and the rim pattern was manufactured. The reduced drawing process provided advantages of low cost and short manufacture TAT (Turn Around Time). This was effective in manufacturing SoC which requires TAT, since manufacture of 90 nm-diameter-LSIs requires approximately 12 hours to 24 hours drawing time.

### Third Embodiment

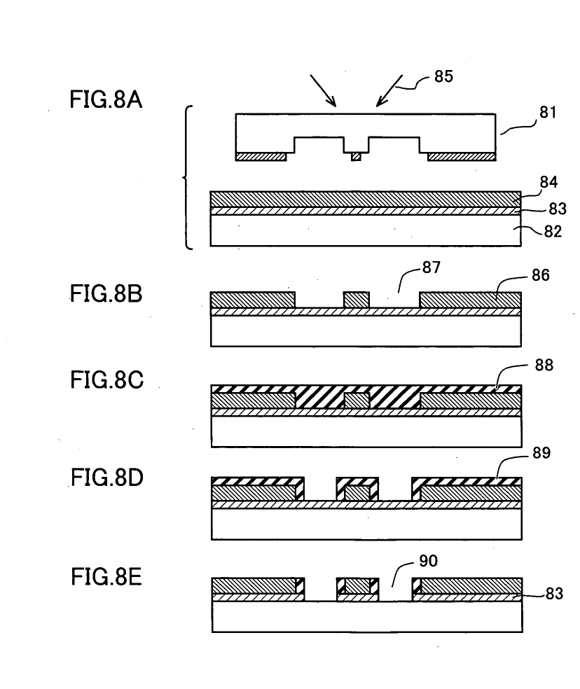

A third embodiment will be described with reference to FIGS. 8A to 8E illustrating a wafer process flow. In this embodiment, a mask including a larger (broadened) opening portion of the main pattern, based on the photomask illustrated in the first embodiment, was employed. More specifically, while in the first embodiment the width of the opening portion (w1 in FIG. 4B) of the main hole pattern was set to 440 nm on the mask, in this embodiment a mask having an opening portion with a width of 520 nm (130 nm on the scale on the wafer) was employed. Here, the minimum pattern pitch was 200 nm on the wafer, and thus 800 nm on the mask. The rim width (w2 in FIG. 4B) was set to 100 nm on the scale of mask (25 nm on the scale on the wafer).

Thus, the minimum half tone pattern width between the patterns (w3 in FIG. 4B) was 80 nm on the mask. Even though the half tone pattern width was 80 nm and was fine, the distance to an adjacent pattern (w1+w2+w2 in FIG. 4B) was 720 nm on the mask, and thus abrasions of the fine half tone pattern did not occur. Abrasions may occur during wet cleaning processes. However, there was a large distance between patterns, which weaken capillary forces (capillary forces caused by interfacial tensions) which generate during drying in the cleaning process. Furthermore, the mask included no micro-width pattern such as patterns smaller than 200 nm, which enabled visual mask inspections. Further, quasi-defects were not generated.

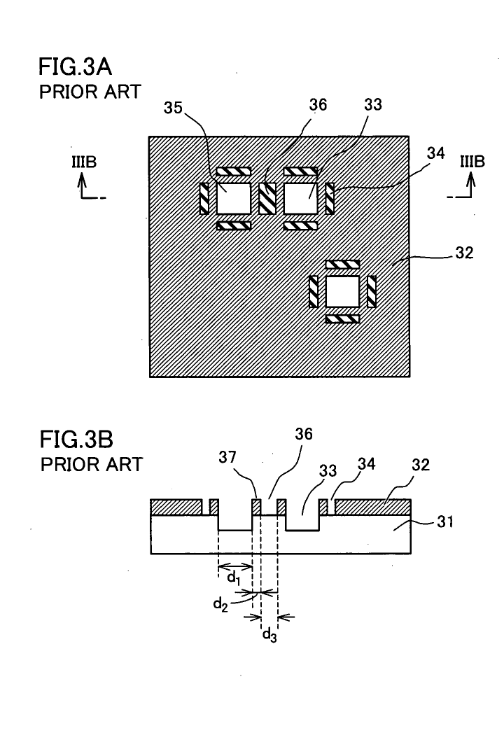

On the other hand, in the case of an OL-PSM including field regions and main pattern portions formed to be in phase for exposure light, the main opening pattern was broadened to 80 nm on the mask as in the present embodiment, and accordingly the half tone partition wall pattern width (d2 in FIG. 3B) and the secondary pattern width (d3 in FIG. 3B) were 70 nm and 140 nm, respectively, on the mask. Since there is a short distance of 140 nm between adjacent half tone partition wall patterns, large capillary forces acted thereon, causing abrasions during mask cleaning. Further, since micro-patterns with widths of 70 nm, 140 nm and 70 nm were aligned adjacent to one another, visual mask inspections could not be performed.

As illustrated in FIG. 8A, a photoresist 84 formed on a wafer 82 was exposed to light using a photomask 81 according to the present embodiment. The light exposure was performed through a projection lens. Here, an oblique-incident illumination 85 was employed as an illumination. This mask improves the resolution and the light exposure margin when it is irradiated with oblique-incident illumination. Here, ⅔ annular illumination was employed as the oblique-incident illumination. Alternatively, quadrupole illumination or double-pole illumination may be employed depending on the pattern layout. Further, in FIG. 8A to 8E, a coating type antireflection film was employed as an antireflection film 83. Also, antireflection film 83 may be an antireflection film formed by CVD. In the case where there is low reflection at the substrate, this antireflection film may be eliminated.

Then, as illustrated in FIG. 8B, a resist pattern 86 was formed by performing a development. The hole pattern 87 had a dimension of 110 nm and was larger than the desired dimension 90 nm. Since the hole had a larger dimension, the light exposure margin was further improved over the first embodiment. Thus, the depth of focus was 300 nm for a 200-nm-pitch pattern to an isolated pattern. Then, as illustrated in FIG. 8C, a film 88 which forms a mixing layer with the resist when subjected to heat treatment is formed by coating, and then heat treatment was performed. Then, development was performed to form a mixing layer 89 surrounding resist pattern 86 to narrow the pattern opening, as illustrated in FIG. 8D. Then, as illustrated in FIG. 8E, antireflection film 83 was etched to form a resist pattern 90 having a desired hole diameter.

The series of hole reduction procedures are called as a hole shrink. In this case, the hole diameter was 90 nm and the minimum pattern pitch was 200 nm. As previously described, the depth of focus was 300 nm. There was no mask defect generated, and also mask defect inspections could be performed, which increased the yield. Also, this method was employed to form a pattern with a hole diameter of 80 nm and a minimum pitch of 180 nm. In this case, the depth of focus was 250 nm.

While in this embodiment, a method which applies a film which mixes with the resist was employed for the hole shrink, formation of micro-patterns could be achieved by other various methods as follows; a method which heats the resist in the presence of oxygen to cause cross-linking in order to leave a film, a method which forms a heat shrinkable film by coating and then performs heat treatment to pull the soften resist pattern, and a method which simply performs a heat treatment to cause the resist to flow in order to achieve a hole shrink. The simple heat treatment method has an advantage of ease and low material cost. With the heat shrinkable film coating method, the hole is shrunk depending on the volume of the heat shrinkable film embedded in the hole, and larger patterns shrink largely and smaller patterns shrink little. Thus, the pattern dimensions were made nearly constant, and therefore this method was preferable in improving the dimension accuracy. As the heat shrinkable film, a polyvinylpyrrolidone resin-based resin or material may be utilized.

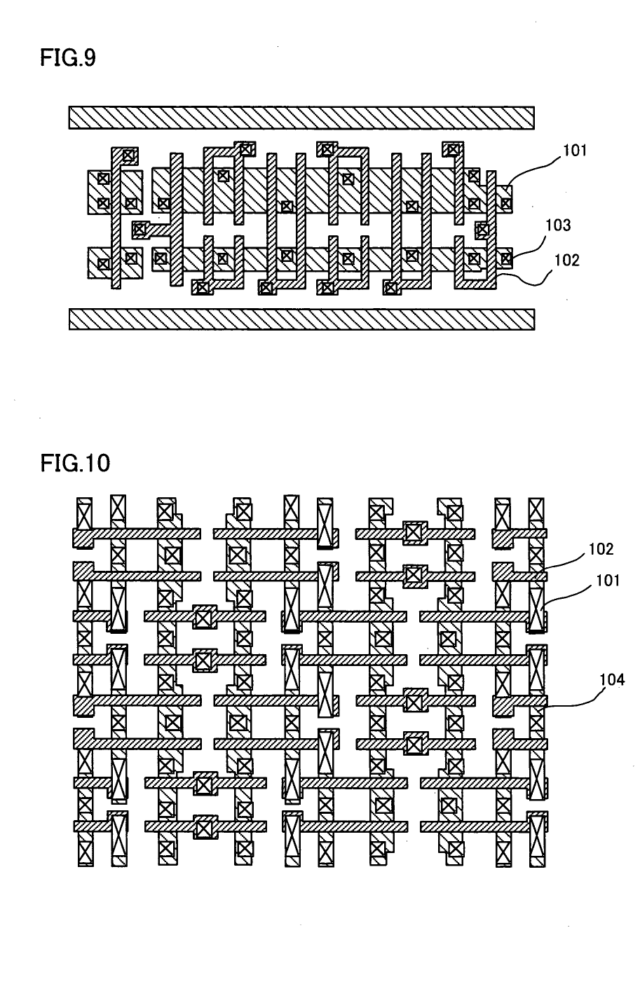

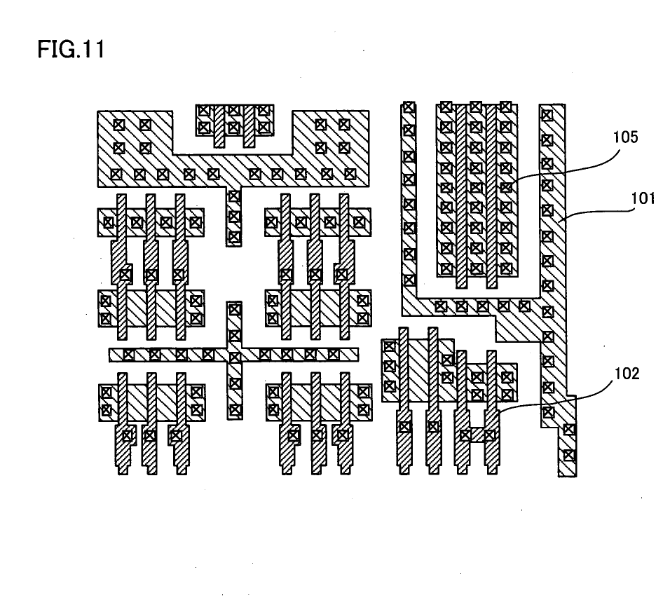

An example of application of the present technique to a logic LSI will be described using FIGS. 9, 10 and 11. FIGS. 9, 10, and 11 illustrate the pattern layouts of a logic section, SRAM (Static Random Access Memory) memory cell section, and a SRAM peripheral circuit section, respectively. In these figures, a diffusion layer (active region) 101, a gate wiring 102, a contact hole (conducting hole) 103, 104 and 105 are disclosed. For 65-nm nodes, the minimum contact diameter was 90 nm, and the minimum pattern pitch was 200 nm. The present light exposure technique was applied to only the contact holes. The logic section has a relatively small distance between contact holes 103, the SRAM memory cell section includes rectangular holes 104, and the SRAM peripheral circuit section includes dense contact holes 105. These contact holes were all formed with a dimension accuracy of ±11 nm and a high yield. With a conventional half tone phase shift method, pattern resolution was not achieved, and with an OL-PSM method, the problem of mask defect was not overcome.

### Fourth Embodiment

A custom LSI was manufactured using a photomask according to a fourth embodiment. The present photomask was applied to a contact hole layer forming process for establishing an electric connection with a diffusion layer and a first via hole layer forming process for establishing an electric connection between a gate wiring and a first wiring layer. A five-layers wiring custom LSI was manufactured and for formation of the via hole layers other than the first via hole layer for establishing connections with other wiring layers, a conventional half tone phase shift mask was employed in which there was a phase difference (for exposure light) of π between the field region and the main pattern region. For formation of the contact layer, a mask according to the second embodiment which offers high resolution was employed since the hole diameter is 90 nm and so small. For formation of the first via layer, a mask according to the second embodiment was employed in order to ensure a sufficient light exposure contrast, since the minimum diameter was 100 nm and thus relatively large, but it was necessary to process a thick interlayer film and accordingly a resist film thickness of 300 nm was required. For forming the via layers other than the first via layer, a half tone phase shift mask excellent in the mask manufacture TAT was employed since it is subjected to many customer specification changes as a custom device, requiring a mask TAT. With this method, it becomes possible to manufacture a custom LSI with a minimum diameter of about 90 nm.

Although the present invention has been described and illustrated in detail, it is clearly understood that the same is by way of illustration and example only and is not to be taken by way of limitation, the spirit and scope of the present invention being limited only by the terms of the appended claims.

1. A half-tone-phase-shift type photomask comprising:
a field region which attenuates exposure light; and
a pattern region which transmits the exposure light, wherein exposure light passed through said field region and exposure light passed through said pattern region are substantially in phase, a rim region which transmits exposure light is provided outside of and provided to come in contact with said pattern region, and exposure light passed through said rim region has substantially an opposite phase relative to the phase of exposure light passed through said field region and exposure light passed through said pattern region.

2. The photomask according to claim 1, wherein
said rim region has a line width which is in the range of from 1/6 to ⅓ of the line width of said pattern region.

3. A photomask manufacturing method comprising the steps of:
forming, on a glass substrate, a so-called half tone film which attenuates exposure light and inverts the phase of exposure light passed therethrough with respect to the phase of exposure light which did not pass through the film;
forming a half tone pattern by forming a resist pattern on said half tone film and etching away the half tone film within a resist opening;
etching said glass substrate within said resist opening to a depth which causes exposure light passed through the etched opening portion to have substantially the same phase as that of exposure light passed through said half tone film;
widening the opening portion of said half tone pattern by isotopic etching; and
removing said resist pattern.

4. A semiconductor device manufacturing method comprising forming a semiconductor device using:
a half-tone-phase-shift type photomask including a field region which attenuates exposure light and a pattern region which transmits the exposure light wherein exposure light passed through said field region and exposure light passed through said pattern region are substantially in phase, a rim region which transmits exposure light is provided outside of and provided to come in contact with said pattern region, and exposure light passed through said rim region has substantially an opposite phase relative to the phase of exposure light passed through said field region and exposure light passed through said pattern region.

5. The semiconductor device manufacturing method according to claim 4 further comprising forming hole patterns using said half tone phase shift type photomask.

6. The semiconductor device manufacturing method according to claim 5 further comprising performing patterning of a contact hole layer for establishing connection with substrate active layer and patterning of a first via hole layer for establishing connection between a gate electrode and a wiring layer using said half-tone-phase-shift type photomask.

7. The semiconductor device manufacturing method according to claim 5 further comprising the steps of:
forming a resist hole pattern having an opening larger than a desired dimension; and
adjusting said resist hole pattern to a desired dimension by resist shrink method, wherein
said forming the resist hole pattern is performed using said half-tone-phase-shift type photomask.

8. The semiconductor device manufacturing method according to claim 7, wherein
said resist shrink method is performed by heat treatment.

9. The semiconductor device manufacturing method according to claim 7, wherein
said resist shrink method comprises the steps of forming a coated film, performing heat treatment and removing said coated film.

10. The semiconductor device manufacturing method according to claim 9, wherein
said coated film is a heat shrinkable film.

11. The semiconductor device manufacturing method according to claim 9, wherein
said coated film has a property of mixing with a resist.

12. The semiconductor device manufacturing method according to claim 9, wherein
said coated film is insolubilized when subjected to heat treatment in the presence of oxygen.

13. The semiconductor device manufacturing method according to claim 4, wherein
said exposure light is an oblique-incident light on the photomask.

14. The semiconductor device manufacturing method according to claim 4, further comprising forming a semiconductor device using:
a half tone phase shift mask in which exposure light passed through the field region and exposure light passed through the pattern region are substantially in opposite phases.
